(19) United States
(12) Patent Application Publication
(10) Pub. No.: US 2023/0378022 A1
(43) Pub. Date: Nov. 23, 2023

(54) POWER MODULE INTEGRATED CIRCUIT PACKAGE

(71) Applicant: TEXAS INSTRUMENTS INCORPORATED, Dallas, TX (US)

(72) Inventors: KWANG-SOO KIM, Sunnyvale, CA (US); Vivek Kishorechand Arora, San Jose, CA (US); Woochan Kim, San Jose, CA (US)

(21) Appl. No.: 17/749,311

(22) Filed: May 20, 2022

(51) Int. Cl. H01L 23/373; H01L 25/07; H01L 23/00; H01L 23/498; H01L 21/48

(52) U.S. Cl. CPC H01L 23/3735; H01L 25/072; H01L 24/48; H01L 23/49861; H01L 21/4839; H01L 23/49822; H01L 23/49844; H01L 2924/1033; H01L 2924/1306; H01L 2224/48245; H01L 24/32; H01L 2224/32227; H01L 2224/73265; H01L 24/73; H01L 2224/48137

(57) ABSTRACT

A power module includes an interconnect of an integrated circuit (IC) package having a heat slug. The power module also includes a direct bonded copper (DBC) substrate. The DBC substrate has a first surface formed of pattern copper, the patterned copper has a pad and a second surface that opposes the first surface, the second surface has a sheet of copper. The second surface of the DBC substrate is thermally coupled to the heat slug. The power module further includes a die mounted on the pad of the first surface of the DBC substrate. The die has a power transistor. The die and the heat slug are thermally coupled and electrically isolated.

### TECHNICAL FIELD

The present disclosure relates to a power module and more specifically, to a power module integrated circuit (IC) package that includes a direct bonded copper substrate.

### BACKGROUND

A heat slug is a metal plate that draws heat away from silicon components of an integrated circuit (IC) package. In some examples, the heat is drawn toward a heat-sink. Thermal performance in IC packages with high power ratings (e.g., approximately 3.6-7.0 kW) are dependent on a heat slug or heat spreader in the IC package. The heat slug is a single piece structure in the IC package. Thus, reducing a thermal resistance of the IC package below a desired value is difficult due to the single piece structural configuration of the heat slug. In addition, circuit topologies, power output, and package layout are limited due to the single piece heat slug structure. Finally, the single piece heat slug structure cannot provide external isolation that is required with additional isolation materials such as an isolated thermal interface material or other structures to assemble with external systems or heat sinks.

Direct bonded copper (DBC) substrates have a high thermal conductivity, and are used in power modules. DBC substrates include a ceramic tile (commonly alumina) with a sheet of copper bonded to one or both sides by a high-temperature oxidation process. The top copper layer is preformed prior to firing or chemically etched using printed circuit board technology to form an electrical circuit, while the bottom copper layer is usually a sheet of copper.

### SUMMARY

A first example relates to a power module that includes an interconnect of an integrated circuit (IC) package that includes a heat slug. The power module also includes a direct bonded copper (DBC) substrate. The DBC substrate includes a first surface formed of pattern copper, the patterned copper having a pad. The DBC substrate also includes a second surface that opposes the first surface, the second surface has a sheet of copper. The second surface of the DBC substrate is thermally coupled to the heat slug. The power module also includes a die mounted on the pad of the first surface of the DBC substrate. The die includes a power transistor. The die and the heat slug are thermally coupled and electrically isolated.

A second example relates to a method for forming a power module. The method includes attaching a die with a power transistor to a pad patterned on a first surface of a direct bonded copper (DBC) substrate. The method also includes mounting a second surface of the DBC substrate formed of a sheet of copper on a heat slug of an interconnect of an IC package. The die and the heat slug are thermally coupled and electrically isolated.

### BRIEF DESCRIPTION OF THE DRAWINGS

FIG. 1 illustrates a diagram of a power module with a direct bonded copper (DBC) substrate mounted on an interconnect that includes a heat slug.

FIGS. 2A and 2B illustrate a side view and a plan view, respectively, of an example of a power module with a DBC substrate mounted on an interconnect that includes a heat slug.

FIG. 3 illustrates a power module that implements a power stage power supply.

FIG. 4 illustrates a power module that implements a half-bridge power converter.

FIG. 5 illustrates another power module that implements a half-bridge power converter.

FIG. 6 illustrates a first stage of an example method of fabricating a power module.

FIG. 7 illustrates a second stage of the example method of fabricating a power module.

FIG. 8 illustrates a third stage of the example method of fabricating a power module.

FIG. 9 illustrates a fourth stage of the example method of fabricating a power module.

FIGS. 10A and 10B illustrate a side view and a plan view, respectively, of a fifth stage of the example method of fabricating a power module.

FIGS. 11A and 11B illustrate a side view and a plan view, respectively, of a sixth stage of the example method of fabricating a power module.

FIG. 12 illustrates a flowchart of an example method for fabricating a power module.

### DETAILED DESCRIPTION

This description relates to a power module integrated circuit (IC) package. The power module includes a direct bonded copper (DBC) substrate mounted on a heat slug of an interconnect (e.g., a leadframe). The interconnect is configured for a power small outline package (PSOP). The DBC substrate has a ceramic core (e.g., formed of alumina or aluminum nitride (AIN)) sandwiched between two copper layers. A first (e.g., a top) layer of the DBC substrate is patterned copper that forms pads to receive circuit components, such as dies and/or IC chips. The patterned copper forms a first surface of the DBC substrate. A second (e.g., a bottom) layer of the DBC substrate is a continuous sheet of copper. The continuous sheet of copper forms a second surface of the DBC substrate.

A die that includes a power transistor is mounted on a pad of the first surface of the DBC substrate. In some examples, there are multiple dies on multiple pads of the first surface of the DBC substrate. The second surface of the DBC substrate (formed of the sheet of copper) is thermally coupled to the heat slug. The ceramic core of the DBC substrate electrically isolates the heat slug from the die, thereby curtailing electromagnetic interference (EMI) between the die and the heat slug. Also, in some examples, the heat slug is coupled to an external heat sink that is coupled to an electrically neutral node (e.g., ground). Because the heat slug is electrically isolated from the die, short circuits between the electrically neutral node and the die are avoided. Additionally, the DBC substrate provides thermal coupling between the die and the heat slug to curtail thermal resistance of the power module.

FIG. 1 illustrates a diagram of a power module 100 with a direct bonded copper (DBC) substrate 104 mounted on an interconnect 108 (e.g., a leadframe) that includes a heat slug 112. The power module 100 is implemented as an integrated circuit (IC) package, such as a power small outline package (PSOP). The DBC substrate 104 has a first surface 116 and a second surface 120 that sandwich a ceramic core 124. The ceramic core 124 is formed of alumina or aluminum nitride (AIN).

The second surface 120 of the DBC substrate 104 is formed of a continuous sheet of copper 128. The first surface 116 of the DBC substrate 104 is formed of patterned copper. In the example illustrated, the patterned copper on the first surface of the DBC substrate 104 forms a first pad 132 and a second pad 136 separated by a gap 138. The sheet of copper 128 and the patterned copper (forming the first pad 132 and the second pad 136) have the same thickness. This thickness is about 0.127 millimeters (mm) to about 0.30 mm in various examples. Unless otherwise stated, in this description, ‘about’ preceding a value means+/−10 percent of the stated value. The ceramic core 124 has a thickness of about 0.32 mm to about 0.38 mm.

A layer of thermal adhesive 140, such as solder paste underlies the sheet of copper 128 to thermally couple the DBC substrate 104 to the heat slug 112 of the interconnect 108. The layer of thermal adhesive 140 is about 0.025 mm thick.

A first die 144 is mounted on the first pad 132 and a second die 148 is mounted on the second pad 136 with a layer of thermal adhesive 152, such as solder paste, with a thickness of about 0.025 mm. In other examples, there are more or less dies. The first die 144 and the second die 148 include a power transistor, such as a gallium nitride (GaN) field effect transistor (FET). The interconnect 108 includes leads 156 that are configured to be coupled to external devices. Wire bonding 160 couples the first die 144 and the second die 148 to the leads 156. A molding 164 encapsulates the power module 100. In some examples, the molding 164 is formed of plastic.

The heat slug 112 is configured to be coupled to a heat sink 168. The heat sink 168 is coupled to an electrically neutral node 172 (e.g., ground). The DBC substrate 104 provides electrical isolation between the first die 144, the second die 148 mounted on the first surface 116 of the DBC substrate 104 and the heat slug 112. In this manner, electromagnetic interference (EMI) between the heat slug 112 and the first die 144 and the second die 148 is curtailed. Also, by electrically isolating the first die 144 and the second die 148 mounted on the first surface 116 of the DBC substrate 104 from the heat slug 112, short circuits between the electrically neutral node 172 and the dies are avoided, while maintaining a robust thermal performance. More particularly, mounting the DBC substrate 104 on the heat slug 112 of the interconnect 108 thermally couples the first die 144 and the second die 148 to the heat slug 112, and provides a thermal resistance of about 1.8 Kelvin per watt (K/W) to about 1.47 K/W. In various examples, the power module 100 is configured as a power supply, a half-bridge power converter, etc. The power module 100 has an output power of about 3 kilowatts (kW) to about 10 kW.

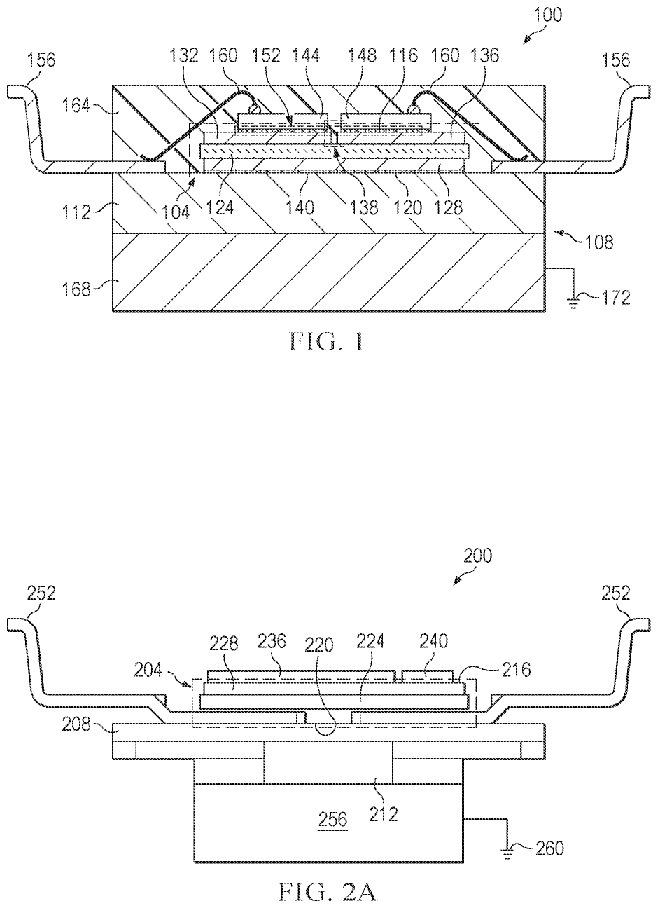

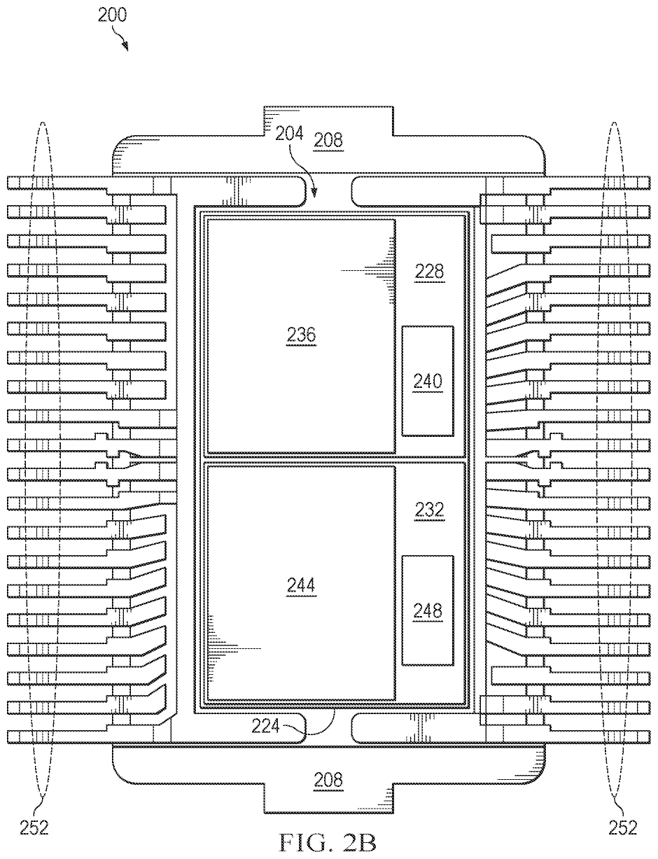

FIGS. 2A and 2B are a side view and a plan view, respectively of an example of a power module 200 with a direct bonded copper (DBC) substrate 204 mounted on an interconnect 208 (e.g., a leadframe) that includes a heat slug 212. The power module 200 is employable to implement the power module 100 of FIG. 1. The power module 200 is implemented as an IC package, such as a PSOP. The DBC substrate 204 has a first surface 216 and a second surface 220 that sandwich a ceramic core 224. The ceramic core 224 is formed of alumina or aluminum nitride (AIN).

The second surface 220 of the substrate 204 is a sheet of copper and is configured to thermally couple the DBC substrate 204 and the heat slug 212. The first surface 216 of the substrate 204 has copper patterned to receive circuit components. In the example illustrated, the first surface 216 has a first pad 228 and a second pad 232. There is a first die 236 and a first control module 240 (e.g., an IC chip and/or a printed circuit board with circuit components) mounted on the first pad 228 of the DBC substrate 204. Also, a second die 244 and a second control module 248 (another IC chip and/or a printed circuit board with circuit components) are mounted on the second pad 232 of the DBC substrate 204. In other examples, there are more or less dies. For instance, in some examples, there is a single die mounted on the first surface 216 of the DBC substrate 204.

In some examples, the first die 236 and the second die 244 include a power transistor. More particularly, the first die 236 and the second die 244 include a GaN FET in some examples. The power module 200 is configured to output power of about 3 kilowatts to about 10 kilowatts.

The interconnect 208 includes leads 252 that are configured to interface with external components. Wire bonds are employable to couple the leads 252 to components of the power module 200, such as the first die 236, the first control module 240, the second die 244 and the second control module 248. The heat slug 212 is configured to be thermally coupled to a heat sink 256. The heat sink 256 is coupled to an electrically neutral node 260 (e.g., ground).

The DBC substrate 204 provides electrical isolation between dies mounted on the first surface 216 (including the first die 236, the first control module 240, the second die 244 and the second control module 248) and the heat slug 212. In this manner, electromagnetic interference (EMI) between the heat slug 212 and the dies mounted on the first surface 216 is curtailed. Also, by electrically isolating the dies mounted on the first surface 216 of the DBC substrate 204 from the heat slug 212, short circuits between the electrically neutral node 260 and the dies are avoided, while maintaining a robust thermal performance.

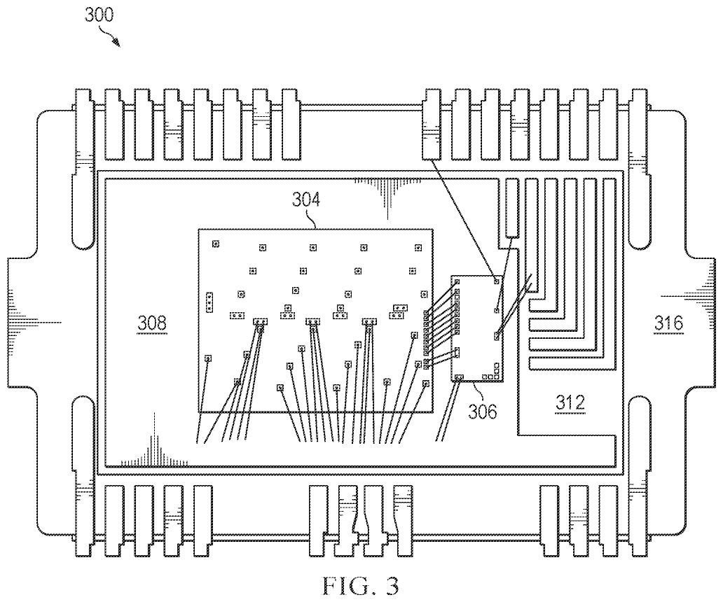

FIGS. 3-5 demonstrate a variety of circuit architectures employable in a power module with a DBC substrate mounted on a heat slug of an interconnect for an IC package, such as a PSOP. More particularly, FIG. 3 illustrates a plan view of a power module 300 that implements a power stage power supply. The power module 300 is employable to implement the power module 100 of FIG. 1. The power module 300 includes a die 304 with a GaN FET embedded therein that is mounted on a pad 308 of a DBC substrate 312. The power module 300 also includes a control module 306 (e.g., an IC chip and/or a printed circuit board with circuit components) mounted on the pad 308 of the DBC substrate 312. The DBC substrate 312 is mounted on an interconnect 316 that includes a heat slug (hidden from view), such as an interconnect for a PSOP.

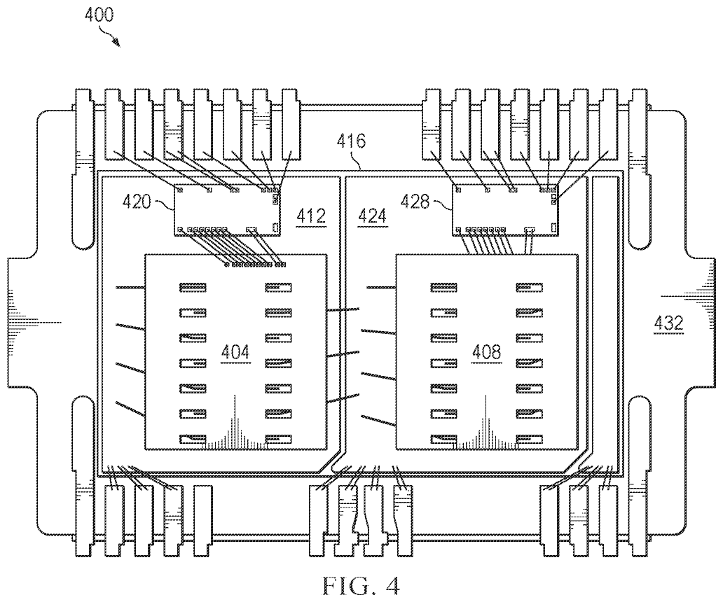

FIG. 4 illustrates a plan view of another power module 400 that implements a half-bridge power converter. The power module 400 is employable to implement the power module 100 of FIG. 1. In various examples, the power module 400 implements a direct current (DC)-to-DC power converter, an alternating current (AC)-to-DC power converter or a DC-to-AC power converter. The power module 400 includes a first die 404 and a second die 408 that have GaN FETs embedded therein. The first die 404 is mounted on a first pad 412 of a DBC substrate 416. The power module 400 also includes a first control module 420 (e.g., an IC chip and/or a printed circuit board with circuit components) mounted on the first pad 412 of the DBC substrate 416. The second die 408 is mounted on a second pad 424 of the DBC substrate 416. A second control module 428 (e.g., an IC chip and/or a printed circuit board with circuit components) is also mounted on the second pad 424 of the DBC substrate 416. The DBC substrate 416 is mounted on a heat slug (hidden from view) of an interconnect 432, such as an interconnect for a PSOP.

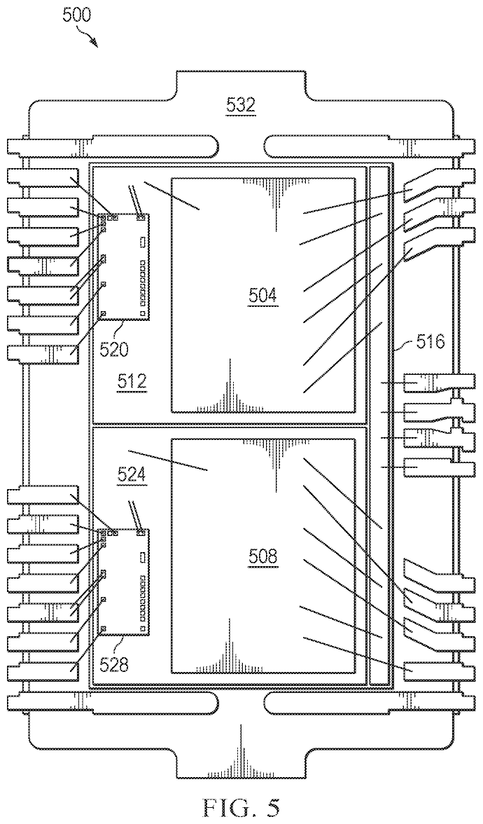

FIG. 5 illustrates a plan view of yet another power module 500 that implements a half-bridge power converter. The power module 500 is employable to implement the power module 100 of FIG. 1. In various examples, the power module 500 is a DC-to-DC power converter, an AC-to-DC power converter or a DC-to-AC power converter. The power module 500 includes a first die 504 and a second die 508 that have GaN FETs embedded therein. The first die 504 is mounted on a first pad 512 of a DBC substrate 516. The power module 500 also includes a first control module 520 (e.g., an IC chip and/or a printed circuit board with circuit components) mounted on the first pad 512 of the DBC substrate 516. The second die 508 is mounted on a second pad 524 of the DBC substrate 516. A second control module 528 (e.g., an IC chip and/or a printed circuit board with circuit components) is also mounted on the second pad 524 of the DBC substrate 516. The DBC substrate 516 is mounted on an interconnect 532 with a heat slug (hidden from view), such as an interconnect for a PSOP.

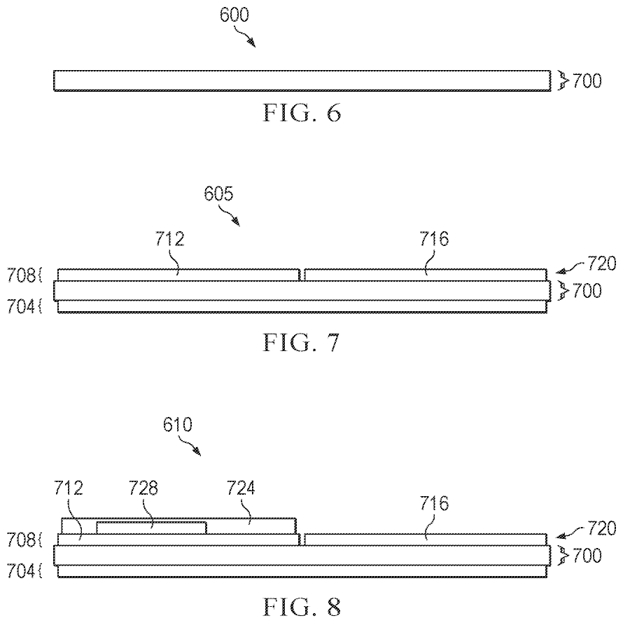

FIGS. 6-9, 10A, 10B, 11A and 11B illustrate a method for fabricating a power module, such as the power module 100 of FIG. 1 and/or the power module 200 of FIGS. 2A and 2B.

As illustrated in FIG. 6, at 600, in a first stage, a ceramic core 700 is provided. In various examples, the ceramic core 700 is formed of alumina or aluminum nitride (AIN).

As illustrated in FIG. 7, at 605, in a second stage, a continuous sheet of copper 704 is adhered to a first surface of the ceramic core 700, and patterned copper 708 is adhered to a second surface of the ceramic core 700. In the example illustrated, the patterned copper 708 forms a first pad 712 and a second pad 716, but in other examples, there are more or less pads. The resultant structure is a DBC substrate 720.

As illustrated in FIG. 8, at 610, in a third stage, a first die 724 is mounted on the first pad 712 of the DBC substrate 720. Also, in the third stage, a first control module 728 is mounted on the DBC substrate 720.

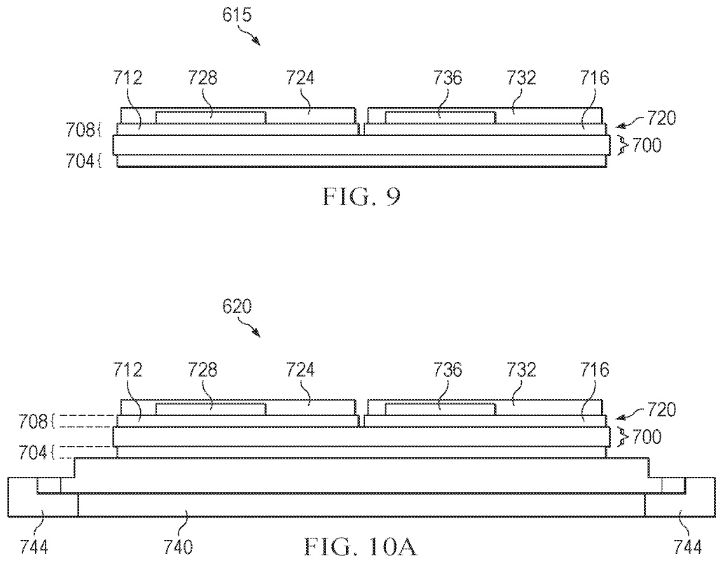

As illustrated in FIG. 9, at 615, in a fourth stage, a second die 732 is mounted on the second pad 716 of the DBC substrate 720. Also, in the fourth stage, a second control module 736 is mounted on the DBC substrate 720.

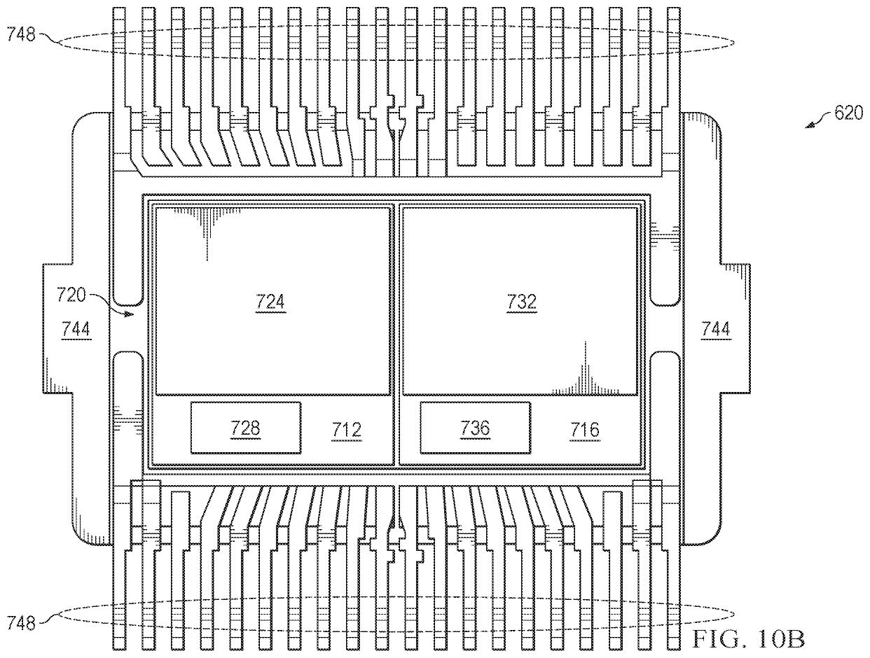

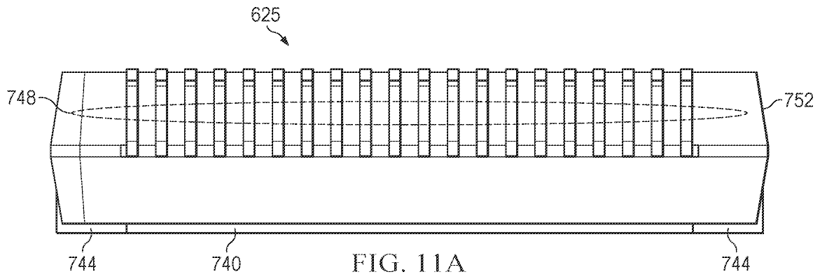

As illustrated in FIG. 10A (a cross-section view) and FIG. 10B (a plan view), at 620, in a fifth stage, the DBC substrate 720 is mounted on a heat slug 740 of an interconnect 744. The interconnect 744 is an interconnect for a PSOP, and includes leads 748 (hidden from view in FIG. 10A) for enabling communication with external devices. In this manner, the DBC substrate 720 is thermally coupled to the heat slug 740. Also, the heat slug is electrically isolated from the dies of the power module, including the first die 724, the first control module 728, the second die 732 and the second control module 736.

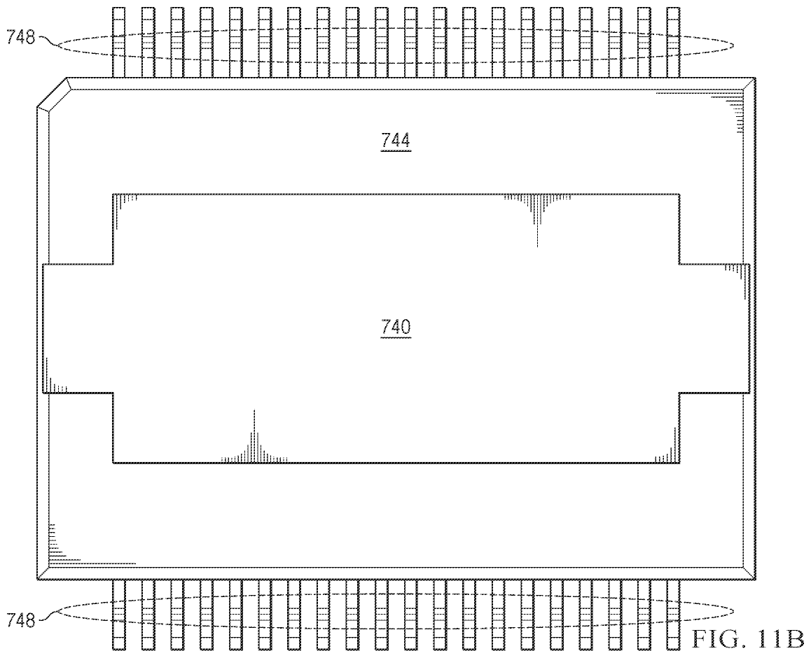

As illustrated in FIG. 11A (a side view) and FIG. 10B (a bottom view), at 625, in a fifth stage, a molding 752 (e.g., plastic) is applied to the DBC substrate 720 and the interconnect 744 encapsulating the circuit components. As illustrated in FIG. 11B, the heat slug 740 extends between edges of the interconnect 744 to increase thermal conductivity. In some examples, the heat slug 740 is thermally coupled to a heat sink.

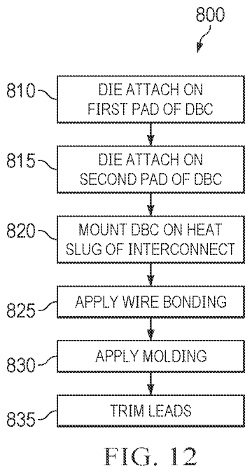

FIG. 12 illustrates a flowchart of an example method 800 for fabricating a power module, such as the power module 100 of FIG. 1 and/or the power module 200 of FIGS. 2A and 2B. At 810, a first die (e.g., the first die 144 of FIG. 1) is attached to a first pad on a first side of a DBC substrate (e.g., the DBC substrate 104 of FIG. 1). At 815, a second die (e.g., the second die 148 of FIG. 1) is attached to a second pad on the first side of the DBC substrate.

At 820, a second side (opposing the first side) of the DBC substrate is mounted on a heat slug (e.g., the heat slug 112 of FIG. 1) of an interconnect (e.g., the interconnect 108 of FIG. 1). At 825, wire bonding (e.g., the wire bonding 160 of FIG. 1) is attached to couple the first die and the second die to leads (e.g., the leads 156 of FIG. 1) of the interconnect. At 830, molding is applied to encapsulate the power module. At 835, the leads are trimmed.

By implementing the method 800, the DBC substrate electrically isolates the first and second dies from the heat slug of the interconnect. Thus, in situations where the heat slug is coupled to an electrically neutral node (e.g., ground), the first and second dies are not short circuited, and EMI is curtailed. Also, the DBC thermally couples the dies to the heat slug, curtailing thermal resistance.

Modifications are possible in the described embodiments, and other embodiments are possible, within the scope of the claims.

What is claimed is:

1. A power module comprising:
an interconnect of an integrated circuit (IC) package comprising a heat slug;
a direct bonded copper (DBC) substrate comprising:
a first surface formed of pattern copper, the patterned copper comprising a pad; and
a second surface that opposes the first surface, the second surface comprising a sheet of copper, wherein the second surface of the DBC substrate is thermally coupled to the heat slug; and
a die mounted on the pad of the first surface of the DBC substrate, wherein the die comprises a power transistor, and the die and the heat slug are thermally coupled and electrically isolated.

2. The power module of claim 1, wherein the die is a first die, the transistor is a first transistor and the pad is a first pad, the patterned copper forming the first surface of the DBC substrate further comprising a second pad separated from the first pad by a gap, and the power module further comprises:
a second die mounted on the second pad of the first surface of the DBC substrate, wherein the second die comprises a second power transistor.

3. The power module of claim 2, wherein a first control module is mounted on the first pad and a second control module is mounted on the second pad, and the power module is a half-bridge power converter.

4. The power module of claim 1, further comprising a control module mounted on the pad of the first surface of the DBC substrate, wherein the power module is a power stage power supply.

5. The power module of claim 1, wherein the heat slug is configured to be coupled to a heat sink that is coupled to an electrically neutral node.

6. The power module of claim 1, wherein the DBC substrate has a core formed of alumina.

7. The power module of claim 1, wherein the DBC substrate has a core formed of aluminum nitride.

8. The power module of claim 1, wherein the power module has a thermal resistance of about 1.8 Kelvin per watt or less.

9. The power module of claim 1, wherein the power transistor is a gallium nitride (GaN) field effect transistor (FET).

10. The power module of claim 1, wherein the power module has an output power of about 3 kilowatts or more.

11. A method for forming a power module, the method comprising:
attaching a die comprising a power transistor to a pad patterned on a first surface of a direct bonded copper (DBC) substrate; and
mounting a second surface of the DBC substrate formed of a sheet of copper on a heat slug of an interconnect of an integrated circuit (IC) package, wherein the die and the heat slug are thermally coupled and electrically isolated.

12. The method of claim 11, further comprising applying wire bonding to couple the die to leads of the interconnect.

13. The method of claim 11, wherein the die is a first die, the power transistor is a first power transistor and the pad is a first pad, the method further comprising:
attaching a second die comprising a second power transistor to a second pad of the first surface of the DBC substrate, wherein the first pad and the second pad are separated by a gap.

14. The method of claim 13, further comprising:
attaching a first control module to the first pad of the DBC substrate; and
attaching a second control module to the second pad of the DBC substrate.

15. The method of claim 14, further comprising:
applying molding to encapsulate the power module, wherein the heat slug is configured to be coupled to a heat sink coupled to an electrically neutral node.

16. The method of claim 13, wherein the power module has an output power of about 3 kilowatts or more.

17. The method of claim 15, wherein the power module has a thermal resistance of about 1.8 Kelvin per watt or less.

18. The method of claim 11, wherein the power transistor is a gallium nitride (GaN) field effect transistor (FET).

19. The method of claim 11, wherein the DBC substrate has a core formed of alumina.

20. The method of claim 11, wherein the DBC substrate has a core formed of aluminum nitride.
